(19) United States
(12) Patent Application Publication
(10) Pub. No.: US 2011/0234242 A1
(43) Pub. Date: Sep. 29, 2011

(54) FORKLIFT TRUCK WITH A DEVICE FOR DETECTING A WEIGHT LOAD

(75) Inventor: Stephan Gerster, Wachtberg-Pech (DE)

(73) Assignee: SOEHNLE PROFESSIONAL GMBH & CO. KG, Backnang (DE)

(21) Appl. No.: 13/069,506

(22) Filed: Mar. 23, 2011

(30) Foreign Application Priority Data
Mar. 24, 2010 (DE) 10 2010 012 670.5

(51) Int. Cl. G01R 27/28; G01R 19/00; G01B 5/30

(52) U.S. Cl. 324/654; 324/76.11; 73/760

(57) ABSTRACT

A forklift includes a chassis component having an opening in the form of one of a recess and a cutout; and a measuring element disposed in the opening and configured to record and translate changes in at least one of the geometric shape and size of the opening into electrical measurement signals dependent on a magnitude of the changes.

### CROSS REFERENCE TO PRIOR APPLICATIONS

Priority is claimed to German Patent Application No. DE 10 2010 012 670.5, filed Mar. 24, 2010, the entire disclosure of which is hereby incorporated by reference herein.

### FIELD

The present invention relates to a forklift having a device for sensing a weight load.

### BACKGROUND

When improperly operated, forklifts can tip over, particularly when lifting a load. It is known, for example, to use force measurement to sense the load on the rear axle, thus the axle load, in order to determine the tipping danger; at the onset of tipping, the axle load is equal to zero.

The German Patent Application DE 34 22 837 A1 describes a front-end forklift having a device for measuring the load on an axle. In one specific embodiment, pressure force sensors are provided at the axle bearings to measure the axle load. The inherent disadvantage of this design is that transversal forces occurring at the axle bearings falsify the measuring result to a considerable degree, particularly during vehicle operation. In another variant, elastic deformations of the axle body are measured using a strain gauge strip. The same problems are associated with this design. Also, very inaccurate measuring results are obtained due to the grey cast iron material mostly used in axle manufacturing.

The German Patent Application DE 10 2006 028 551 A1 discusses a forklift having a rear axle that is provided with a measuring device for sensing the axle load. Besides having a bearing function, one axle component acts at the same time as a shear force sensor or as a normal force sensor within the axle. This design has the disadvantage that accurate enough measurements accompanied by acceptable reproducibility are only attainable in the context of a very precise manufacturing. In particular, the disadvantage of the shear force sensor is that it is sensitive to displacements produced by the application of force. Therefore, substantial deviations arise between the measuring result and the actual axle load, in particular during vehicle operation. Moreover, a defective measuring device disadvantageously entails an extremely costly repair of the forklift since disassembly of the entire axle component is

### SUMMARY

In an embodiment, the present invention provides a forklift including a chassis component having an opening in the form of one of a recess and a cutout. A measuring element is disposed in the opening and configured to record and translate changes in at least one of a geometric shape and a size of the opening into electrical measurement signals. The measurement signals depend on a magnitude of the changes in the at least one of a geometric shape and a size of the opening.

### BRIEF DESCRIPTION OF THE DRAWINGS

The subject matter of the present invention is schematically illustrated in the drawing and is described below with reference to the figures, elements having essentially equivalent functions being denoted by the same reference numerals. In this context:

FIG. 1: is a detail view of the chassis of a forklift according to the present invention;

FIG. 2: shows one particular design variant of the opening and of the configuration of the measuring element that is inserted into the opening;

FIG. 3: shows another design variant of the opening and of the configuration of the measuring element that is inserted into the opening; and

FIG. 4: shows another design variant of the opening and of the configuration of the measuring element that is inserted into the opening.

### DETAILED DESCRIPTION

In an aspect of the present invention a forklift is provided that will make possible a more accurate and reliable determination of the weight load and that will be simpler to service.

In an embodiment, the invention provides a forklift which is characterized in that an opening, namely a recess or a cutout, into which a measuring element is inserted that records changes in the geometric shape and/or size of the opening and that translates these into electrical measurement signals which are dependent on the magnitude of the variations, is incorporated in a chassis component.

In an embodiment of the present invention—different than related-art forklifts—an exceptionally accurate and reproducible measurement of a weight load may be obtained by measuring an opening that is incorporated in the chassis component, namely by measuring the spatial deformation of the opening induced by the mechanical loading of the chassis component. The chassis component may be an axle, a swing axle, a stub axle, an axle support or an axle mount, for example. An accurate measurement is made possible when a plurality of openings are provided in the chassis component whose geometric shapes and/or sizes are monitored by at least one measuring element per opening. The opening(s) is/are preferably configured in such chassis components and positioned at locations where a change in the weight load on the fork lift induces great enough variations in the geometric shape and/or size of the opening, respectively openings.

One benefit of the present invention is derived in that a malfunction of the measuring device normally requires merely removing and/or replacing the measuring element—and not the entire chassis components.

A very direct and reliable operation is provided by one inventive design of the forklift whereby the chassis component is designed as a T-section or as a double-T-section, the opening being configured in the crossbar of the T-section or the double-T-section. A plurality of openings may advantageously be configured mutually symmetrically in the crossbar.

One embodiment of the forklift according to the present invention provides for the measuring element, which records changes in the geometric shape and/or size of the opening and translates these into electrical measurement signals that are dependent on the magnitude of the variations, to be designed as a length measuring element and/or as a distance measuring element.

It may be provided for it to be an optical, in particular an interferometric measuring element, for example.

Alternatively or additionally, the measuring element may be a capacitive measuring element, the distance between two conductive parts being determined on the basis of the capacitance existing between the two, in that, to perform the capacitance measurement, the two mutually isolated parts are incorporated in an electrical resonant circuit or in an astable multivibrator whose frequency is inversely proportional to the capacitance and thus to the distance.

Alternatively or additionally, it may also be provided for the measuring element to function inductively. In this connection, it may be provided for the electrical voltage signal, which is generated by a core located between the coil conductor ends that dips into or emerges from a coil in response to a change in distance within the opening, to be analyzed for the length or distance measurement.

One especially rugged design provides for the measuring element to have strain gauge strips. In particular, the measuring element may have a deformable measuring body that is placed in the opening in such a way that deformations of the opening translate to deformations of the measuring body. The deformations of the measuring body may be captured, for example, by a strain gauge strip configured on the measuring body. An accurate measurement may be obtained in one specific embodiment where the measuring body features a bending bar or a double bending bar. Such a measuring body is ideally positioned within the opening in such a way that a deformation of the opening translates to a deformation of the bending bar, respectively the double bending bar—without play. The bending may be measured with the aid of strain gauge strips, for example.

One realization of the forklift according to the present invention provides that—starting from an unladen, upright standing forklift as a reference point—, the measuring element be designed to be able to sense both decreased, as well as increased distances. For example, if a force transducer is used as a length measuring element in the manner of the present invention, then it must be designed in this realization to be able to record both compressive, as well as tensile forces. This advantageously allows the measuring device to function reliably even when the chassis component is relieved of load, for instance, because a forklift wheel temporarily loses ground contact on uneven ground or because the rear axle is relieved of load due to the heavy loading of the fork. It is particularly important in this case (however, also in the other realizations according to the present invention) that the measuring element be installed without play in the opening in order to avoid measurement errors during the transition from the loaded to the unloaded condition. For example, preferably mutually opposing mounts such as dovetail guides, for example, for accommodating the measuring element with an exact fit, may be provided in the opening.

Alternatively, it may be provided for the measuring element and/or the measuring body to be pretensioned. The pretensioning is selected in accordance with the present invention in such a way that the measuring element, respectively measuring body is always under tension even when the chassis component is completely pressure-relieved. In this manner, it is achieved that—starting from an unladen, upright standing forklift as a reference point—, there is no need for the measuring element to be designed to measure oppositely directed changes in distance. For example, if a force transducer is used in the manner of the present invention as a length measuring element, than it must be designed in this realization merely to record compressive or tensile forces. To produce the pretensioning, a threaded spindle having an adjusting nut may be provided, for example. In accordance with the present invention, the measuring element itself is used to check the correct pretensioning value when it is installed.

Depending on the form of the chassis design of the forklift, the opening(s) may have different basic forms. For example, the opening may have a round, rectangular, square or triangular cross section.

The measuring element may preferably be positioned so as to be adapted to the deformations of the opening that are to be expected. In particular, it may be provided for the measuring element to be placed in the opening in a direction in which significant changes in the geometric shape and/or significant changes in length or distance are to be expected in response to loading of the chassis component. In this respect, the present invention does not rule out any orientation of the measuring element. In particular, it may be horizontally, vertically or diagonally introduced into the opening.

In one embodiment which provides a significant amount of space for lead wires and electronic components within the opening, two brackets project from opposite sides of the opening into the opening space, the measuring element being mounted and/or clamped between the brackets. It is also possible for the measuring element to be configured between one single bracket and the wall of the opening or for it to be mounted and/or clamped exclusively between corners and/or walls of the opening.

In one embodiment of the forklift according to the present invention that functions reliably even under changing ambient temperatures, a means is provided for compensating for temperature-induced changes in the geometric shape and/or size of the opening. The design may be such that the measuring element and/or the measuring body have the same thermal expansion coefficient as the chassis component. It may additionally be provided for the measuring element and/or the measuring body to have the same thermal adaptability over time as the chassis component. This may be accomplished, for example, by installing local insulating materials.

Alternatively or additionally, it may be provided for the ambient temperature and/or the temperature of the chassis component and/or the temperature of the measuring element to be preferably continuously measured and for the measured values ascertained by the measuring element to be corrected by using the correction values to perform an offset correction as a function of temperature. The correction values may, for example, be stored in the memory of the computer which performs the offset correction.

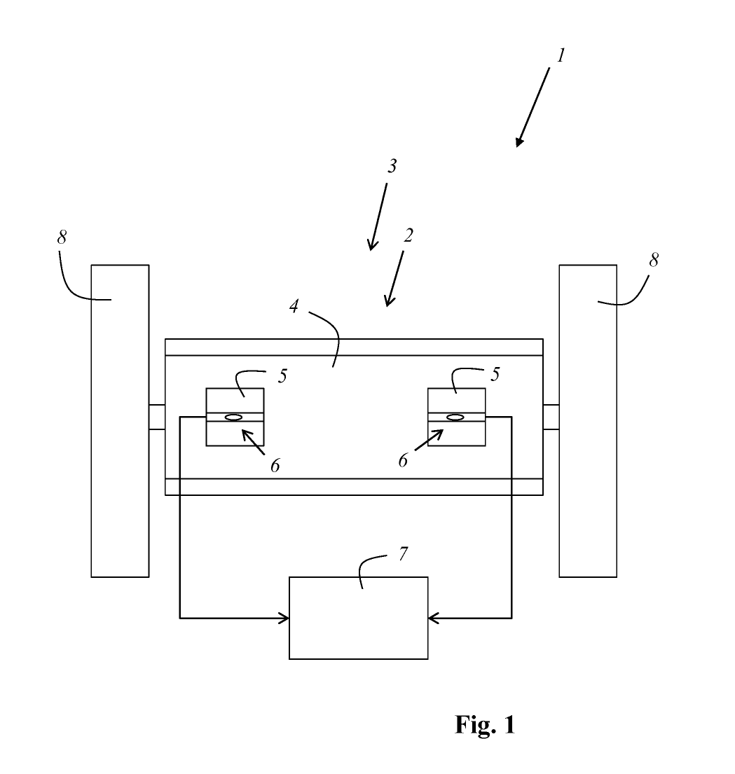

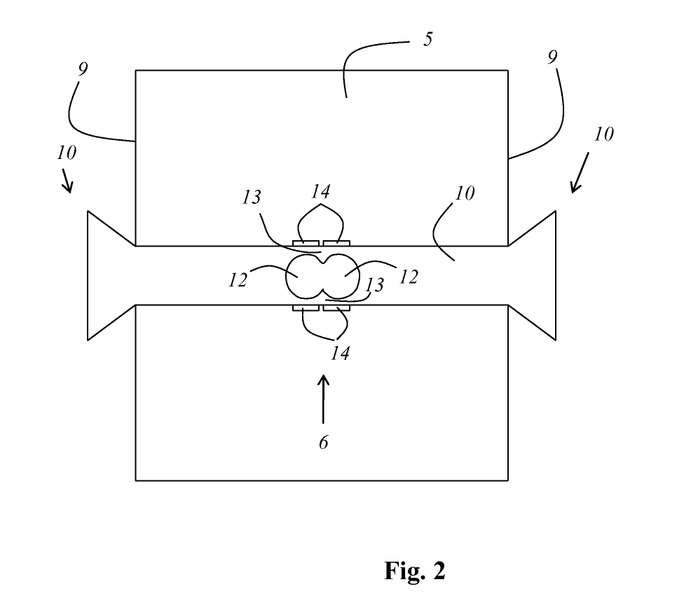

FIG. 1 shows a detail of chassis 1 of a forklift according to the present invention. The forklift has an axle 3 which is designed as a double-T-section 2 and has two wheels 8 mounted thereon. Two rectangular openings 5, namely two cutouts are incorporated in crossbar 4 of double-T-section 2. Inserted into each of openings 5 is a measuring element 6 which records changes in the geometric shape and/or size of opening 5 and which translates these into electrical measurement signals that are dependent on the magnitude of the variations. A detailed representation of an opening 5, together with measuring element 6, is shown in FIG. 2. The electrical measurement signals are transmitted to an evaluation device 7 implemented as a computer, in whose memory, correction values used for temperature compensation are stored. The ambient temperature is measured in parallel using sensors (not shown) and, as a function of the temperature, correction values are selected upon which an offset correction is performed using measured values ascertained from the measurement signals to determine the temperature-corrected measured values.

In a detailed representation, FIG. 2 shows one of openings 5 of double-T-section 2. Incorporated into side walls 9 of opening 5 are mutually opposing dovetail-shaped mounts 10 into which the ends of measuring element 6 are introduced without play. Measuring element 6 has an elongated measuring body 11 having bores 12 in a spectacle-like configuration in the middle region. Formed above and below bores 12 are bending bars 13 which are adhesively bonded to strain gauge strips 14. A deformation of the opening into a trapezoid leads to a parallel bending deformation of the two bending bars 13 and to a measurable change in the electrical resistance of adhesively bonded strain gauge strips 14.

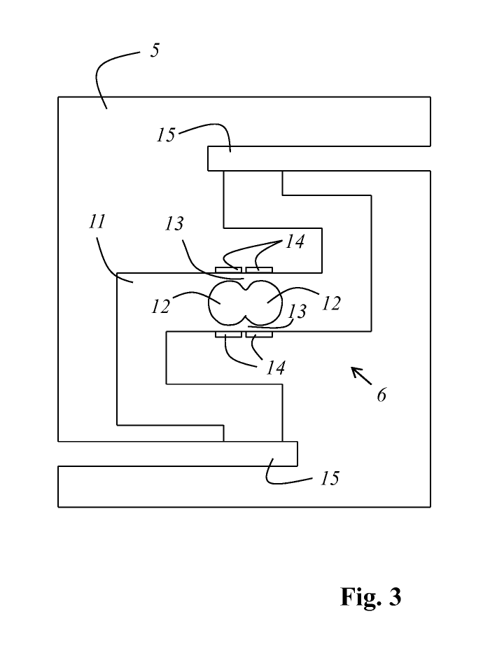

FIG. 3 shows another design variant of opening 5 having a different configuration of measuring element 6 that is inserted into opening 5. Projecting into the opening in this design variant are two brackets 15 between which the s-shaped measuring element 6 is firmly clamped with a predetermined force. The predetermined force is selected in such a way that measuring element 6 is always pressure-loaded, even when the chassis component is completely pressure-relieved. S-shaped measuring body 11 has bending bars 13 which form a double bending bar. Strain gauge strips are adhesively bonded to measuring body 11 above and below the double bending bar.

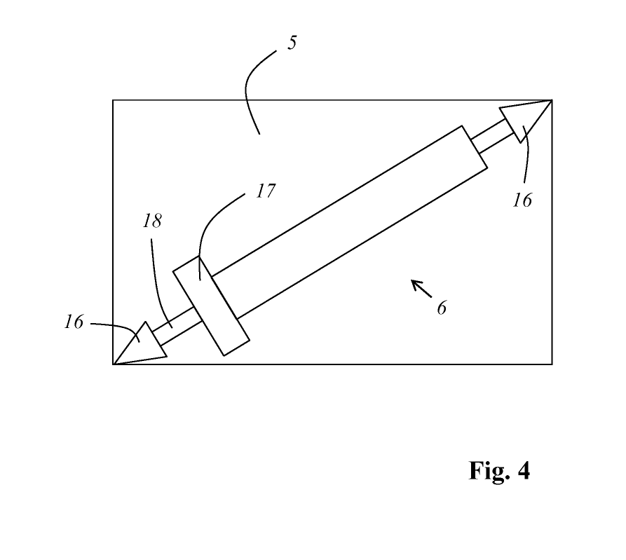

FIG. 4 shows another design variant of opening 5 having another configuration of measuring element 6 that is inserted into opening 5. Measuring element 6 has pointed contact members 16 at its ends and is clamped diagonally into opening 5. The pretensioning is generated with the aid of a threaded spindle 18 and a threaded nut 17 and checked on the basis of the measurement signals emanating from measuring element 6.

The present invention has been described with reference to a specific embodiment. However, it is self-evident that changes and modifications thereto may be made without departing from the protective scope of the claims set forth in the following.

### LIST OF REFERENCE NUMERALS

1 chassis

2 double-T-section

3 axle

4 crossbar

5 opening

6 measuring element

7 evaluation device

8 wheels

9 side walls of opening 5

10 mounts

11 measuring body

12 bores

13 bending bar

14 strain gauge strip

15 brackets

16 contact member

17 threaded nut

18 threaded spindle

1-10. (canceled)

11. A forklift comprising:
a chassis component having an opening in the form of one of a recess and a cutout; and
a measuring element disposed in the opening and configured to record and translate changes in at least one of a geometric shape and a size of the opening into electrical measurement signals, the measurement signals depending on a magnitude of the changes in the at least one of a geometric shape and a size of the opening.

12. The forklift as recited in claim 11, wherein the chassis component includes at least one of an axle, a swing axle, a stub axle, an axle support and an axle mount.

13. The forklift as recited in claim 11, wherein the chassis component includes at least one of a T-section and a double T-section, and wherein the opening is disposed in a crossbar of the at least one of a T-section and a double T-section.

14. The forklift as recited in claim 11, wherein the measuring element includes at least one of a length measuring element and a distance measuring element.

15. The forklift as recited in claim 11, wherein the measuring element includes at least one of an optical measuring element, a capacitive measuring element, an inductive measuring element and a strain gauge strip.

16. The forklift as recited in claim 11, wherein the measuring element includes a deformable measuring body disposed in the opening such that a deformation of the opening corresponds to a deformation of the measuring body.

17. The forklift as recited in claim 16, wherein the measuring body includes a strain gauge strip configured to respond to the deformation of the measuring body.

18. The forklift as recited in claim 16, wherein the measuring body includes at least one of a bending bar and a double bending bar.

19. The forklift as recited in claim 11, wherein the measuring element is pretensioned.

20. The forklift as recited in claim 16, wherein the measuring body is pretensioned.

21. The forklift as recited in claim 11, wherein the opening includes at least one of a round, rectangular, square and triangular cross section.

22. The forklift as recited in claim 11, wherein the measuring element is disposed at least one of horizontally, vertically and diagonally in the opening.

23. The forklift as recited in claim 11, further comprising a temperature compensation device configured to compensate for temperature-induced changes in at least one of the geometric shape and the size of the opening.
